(19) United States
(12) Patent Application Publication
(10) Pub. No.: US 2024/0260473 A1
(43) Pub. Date: Aug. 1, 2024

(54) COMPOSITE MATERIAL FOR POWER GENERATION AND ITS MANUFACTURING PROCESS

(71) Applicant: TOHOKU UNIVERSITY, Sendai-shi, Miyagi (JP)

(72) Inventors: Zhenjin WANG, Sendai-shi (JP); Kohei MARUYAMA, Sendai-shi (JP); Fumio NARITA, Sendai-shi (JP)

(73) Assignee: TOHOKU UNIVERSITY, Sendai-shi, Miyagi (JP)

(21) Appl. No.: 18/563,437

(22) PCT Filed: Jun. 30, 2022
(86) PCT No.: PCT/JP2022/026157

§ 371 Date: Nov. 22, 2023

(30) Foreign Application Priority Data
Jul. 2, 2021 (WO) PCT/JP2021/025058

(51) Int. Cl. H10N 30/092; H10N 30/072; H10N 30/85; H10N 30/853; H10N 30/857

(52) U.S. Cl. CPC H10N 30/092; H10N 30/072; H10N 30/852; H10N 30/8536; H10N 30/857

(57) ABSTRACT

A composite material for power generation having high durability and relatively superior piezoelectric properties, and a method of manufacturing the composite material for power generation. The composite material for power generation has a plate-like shape having a predetermined thickness, and comprises a ceramic material having piezoelectricity and a polymer having piezoelectricity, and is configured so that the content rate of the ceramic material changes continuously and gradually along the thickness direction. It can be manufactured by laminating multiple types of piezoelectric thin films including a ceramic material having piezoelectricity and a polymer having piezoelectricity and having different content rates of the ceramic material so that the content rate of the ceramic material gradually changes along their thickness direction, and then performing heat treating.

### FIELD OF THE INVENTION

The present invention relates to a composite material for power generation, and a method of manufacturing the composite material for power generation.

### DESCRIPTION OF RELATED ART

In recent years, with the spread of the Internet of Things (IoT), energy harvesting devices that can convert a minute amount of energy such as heat, wind, and vibration in the surrounding environment into electrical energy have attracted attention as one of the power sources for IoT devices. As one of the materials for energy harvesting, mentioned is a piezoelectric material which can change mechanical energy into electrical energy. Piezoelectric materials are relatively durable, sensitive to minute strains, and can potentially produce high output power density and output voltage. Piezoelectric materials are also ideal as a power source for IoT devices because they are small, compact, and less susceptible to environmental factors such as humidity.

Piezoelectric ceramic materials are known as a material with excellent piezoelectric properties, but they are disadvantageously susceptible to fatigue cracks when subjected to repeated high-frequency loading, making them difficult to use on their own. Accordingly, to solve this problem, many piezoelectric power generation units have been conventionally used in which a piezoelectric ceramic material is attached to one or both surfaces of a substrate such as a metal elastic plate (see, for example, Patent Literature 1). Piezoelectric composite materials have also been developed in which a ceramic material is added to a flexible polymer (see, for example, Non Patent Literature 1 to 3).

In order to improve bending resistance, a composite piezoelectric element having two first piezoelectric layers and a second piezoelectric layer arranged between the first piezoelectric layers as piezoelectric layers having a resin and piezoelectric particles, in which the volume percent concentration of the piezoelectric particles in the second piezoelectric layer is lower than that of each of the first piezoelectric layers has been proposed (see, for example, Patent Literature 2). This composite piezoelectric element can improve the bending resistance of the second piezoelectric layer by virtue of a low volume percent concentration of the piezoelectric particles in the second piezoelectric layer, and can also improve the bending resistance of the entire piezoelectric layers as compared to a single layer of a piezoelectric material having a high volume percent concentration of piezoelectric particles. Moreover, the piezoelectric performance of the entire piezoelectric layers will not significantly be reduced because the configuration where the second piezoelectric layer is sandwiched between the two first piezoelectric layers having a high volume percent concentration of the piezoelectric particles allows the performance of each of the first piezoelectric layers to be prioritized.

It is noted that Functionally Graded Materials (FGMs) with a concentration gradient of a ceramic material have been studied as one of the piezoelectric composite materials, and demonstrated to have high strength, high toughness, and high fatigue strength (see, for example, Non-Patent Literature 4). Their piezoelectric properties, however, have not yet been confirmed.

### CITATION LIST

### Patent Literature

Patent Literature 1: JP-A-2011-250536
Patent Literature 2: JP-A-2015-50432

### Non Patent Literature

Non Patent Literature 1: Zhenjin Wang, Fumio Narita, “Corona Poling Conditions for Barium Titanate/Epoxy Composites and their Unsteady Wind Energy Harvesting Potential”, Advanced Engineering Materials, 2019, Volume 21, 1900169
Nonpatent Literature 2: Zhenjin Wang, Fumio Narita, “Fabrication of Potassium Sodium Niobate Nano-Particle/Polymer Composites with Piezoelectric Stability and Their Application to Unsteady Wind Energy Harvesters”, Journal of Applied Physics, 2019, Volume 126, 224501
Nonpatent Literature 3: Zhenjin Wang, Hiroki Kurita, Hiroaki Nagaoka, Fumio Narita, “Potassium Sodium Niobate Lead-Free Piezoelectric Nanocomposite Generators Based on Carbon-Fiber-Reinforced Polymer Electrodes for Energy-Harvesting Structures”, Composites Science and Technology, 2020, Volume 199, 108331
Nonpatent Literature 4: Saurav Sharma, Anuruddh Kumar, Rajeev Kumar, Mohammad Talha, Rahul Vaish, “Geometry Independent Direct and Converse Flexoelectric Effects in Functionally Graded Dielectrics: An Isogeometric Analysis”, Mechanics of Materials, 2020, Volume 148, 103456

### SUMMARY OF THE INVENTION

Conventional piezoelectric power generation units, such as those described in Patent Literature 1, require a piezoelectric ceramic material to be attached to a substrate with an adhesive and the like, which disadvantageously may be detached when subjected to repeated vibrations or impacts. In addition, conventional piezoelectric composite materials disadvantageously have poor piezoelectric properties. In the composite piezoelectric element as described in Patent Literature 2, the piezoelectric layers in which a second piezoelectric layer having a different volume percent concentration of piezoelectric particles is sandwiched between two first piezoelectric layers may cause a strain or stress gap at the interfaces between each of the first piezoelectric layers and the second piezoelectric layer when bending load is applied to the piezoelectric layers. For this reason, the piezoelectric layers may disadvantageously be detached and destroyed at these interfaces.

The present invention is made in view of these problems. An object of the present invention is to provide a composite material for power generation having high durability and relatively superior piezoelectric properties, and a method of manufacturing the composite material for power generation.

In order to achieve the above object, a composite material for power generation according to the present invention comprises a ceramic material having piezoelectricity and a polymer having piezoelectricity, and is configured so that the content rate of the ceramic material changes continuously and gradually along a predetermined direction.

A method of manufacturing a composite material for power generation according to the present invention comprises the steps of: laminating multiple types of piezoelectric thin films comprising a ceramic material having piezoelectricity and a polymer having piezoelectricity, the multiple types of piezoelectric thin films having different ceramic content rates of the ceramic material; so that the content rate of the ceramic material gradually changes along their thickness direction, and then performing heat treatment.

The method of manufacturing a composite material for power generation can suitably manufacture the composite material for power generation according to the present invention. The composite material for power generation according to the present invention comprises not only a ceramic material but also a flexible polymer, and is thus more durable than a piezoelectric material consisting only of a ceramic material which is susceptible to repeated loads. In addition, it does not require to be attached to elastic substrates and the like, and is thus highly resistant against vibrations and impacts, showing excellent durability. Moreover, cracking may tend to occur, for example, at an interface where the content rate of a ceramic material changes suddenly. However, the composite material for power generation according to the present invention is configured so that the content rate of a ceramic material changes continuously and gradually. The absence of an interface where the content rate of a ceramic material changes suddenly can prevent cracking and can increase durability.

The composite material for power generation according to the present invention has superior piezoelectric properties as compared to a composite material comprising a ceramic material and a non-piezoelectric material because not only the ceramic material but also the polymer has piezoelectric properties in the composite material for power generation according to the present invention. The composite material for power generation according to the present invention is configured so that the content rate of the ceramic material changes gradually. Therefore, inclusion of the ceramic material and the polymer having different piezoelectric constants each other can confer various properties on the composite material, depending on the magnitude of a value and a changing degree of the content rate thereof. In order to obtain particularly excellent piezoelectric properties, the composite material for power generation according to the present invention preferably comprises a ceramic material having a positive piezoelectric constant and a polymer having a negative piezoelectric constant.

In the method of manufacturing a composite material for power generation according to the present invention, the composite material for power generation can be configured so that the content rate of a ceramic material does not change suddenly at the boundaries of piezoelectric thin films but does change continuously and gradually by laminating multiple types of piezoelectric thin films having different content rates of the ceramic material and then performing heat treatment. This can prevent the boundaries of the piezoelectric thin films from becoming interfaces where the content rate of the ceramic material changes suddenly, which can in turn prevent cracking and detaching at the boundaries of the piezoelectric thin films, and lead to enhanced durability.

In the method of manufacturing a composite material for power generation according to the present invention, the heat treatment may be performed by heating each of the piezoelectric thin films laminated under compression in the direction of their thickness or under no compression of each of the laminated piezoelectric thin films. Moreover, heating is preferably performed at a temperature lower than the recrystallization temperature of each of the piezoelectric thin films. This can prevent deteriorated piezoelectric properties due to recrystallization. The heat treatment can be performed by, for example, hot press in a case where each of the laminated piezoelectric thin films is compressed.

In the method of manufacturing a composite material for power generation according to the prevent invention, each of the piezoelectric thin films is preferably prepared by a spin coating method using a mixture where the ceramic material and the polymer are added and stirred in a solvent. This enables relatively easy preparation of the piezoelectric thin films each having a thin thickness and a uniform concentration. It is noted that piezoelectric thin films may also be prepared by, for example, a solvent casting method other than the spin coating method.

In the method of manufacturing a composite material for power generation according to the present invention, each of the piezoelectric thin films may be laminated after each of the piezoelectric thin films is prepared, or each of the piezoelectric thin films may be laminated by sequentially preparing each of the piezoelectric thin films on top of a piezoelectric thin film already manufactured. In the latter case, the step of laminating each of the piezoelectric thin films pre-prepared may be omitted, enabling more efficient manufacture in a relatively short time as compared to the former.

The composite material for power generation according to the present invention may be configured so that the content rate of the ceramic material increases or decreases continuously and gradually along the predetermined direction. In this case, the composite material for power generation according to the present invention can be manufactured by laminating each of the piezoelectric thin films so that the content rate of the ceramic material gradually increases or decreases along its thickness direction, and then performing the heat treatment. The composite material for power generation according to the present invention has a high power generation efficiency when bent in a predetermined direction (laminating direction) because the piezoelectric constant of one surface side is different from that of the other surface side. For this reason, it can be effectively used, for example, for vibration power generation using vibrations in a predetermined direction.

The composite material for power generation according to the present invention may also be configured so that the content rate of the ceramic material along the predetermined direction is distributed in a plane symmetrical manner with respect to the center plane in the predetermined direction. In this case, in the method of manufacturing a composite material for power generation according the present invention, the composite material for power generation can be manufactured by laminating each of the piezoelectric thin films so that the content rate of the ceramic material along the laminating direction of a laminated body prepared by laminating each of the piezoelectric thin films is in plane symmetry with respect to the center plane in the laminating direction of the laminated body; and then performing the heat treatment. The composite material for power generation according to the present invention has a high power generation efficiency when compressed in a predetermined direction (laminating direction) because the piezoelectric constant is distributed in a plane symmetrical manner with respect to the center plane in the predetermined direction. For this reason, it can be effectively used, for example, for impact power generation using impacts in a predetermined direction.

The composite material for power generation according to the present invention may also be configured so as to have a region where the content rate of the ceramic material increases and a region where the content rate of the ceramic material decreases along the predetermined direction. In this case, in the method of manufacturing a composite material for power generation according the present invention, the composite material for power generation can be manufactured by laminating each of the piezoelectric thin films so as to have a region where the content rate of the ceramic material increases and a region where the content rate of the ceramic material decreases along the laminating direction of a laminated body prepared by laminating each of the piezoelectric thin films; and then performing the heat treatment. The composite material for power generation according to the present invention has a distribution where the piezoelectric constant increases or decreases along a predetermined direction (laminating direction).

In the composite material for power generation according to the present invention and the method of manufacturing the composite material for power generation, the aforementioned ceramic material may comprise any piezoelectric substance, such as those having perovskite structures, for example, barium titanate (BaTiO₃; BTO), potassium sodium niobate [(K,Na)NbO₃; KNN], bismuth sodium titanate [(Bi_{1/2}Na_{1/2})Ti₃; BNT], bismuth ferrite (BiFeO₃; BF), but preferably includes no toxic lead. Those having perovskite structures are ferroelectric, and thus shows piezoelectricity when polarized. The aforementioned polymer may comprise any substance as long as it has piezoelectricity, including, for example, polyvinylidene fluoride (PVDF), P(VDF-TrFE) which is a copolymer of polyvinylidene fluoride and trifluoroethylene, and the like. P(VDF-TrFE) shows piezoelectricity because of the polarization-induced charge bias caused by the difference in electronegativity between hydrogen and fluorine. PVDF must be polarized in a stretched state, but P(VDF-TrFE) does not need to be stretched during polarization.

Preferably, the composite material for power generation according to the present invention has a plate-like shape and a thickness direction which corresponds to the above predetermined direction. Preferably, in the method of manufacturing a composite material for power generation according to the present invention, a laminated body prepared by laminating each of the piezoelectric thin films has a plate-like shape and a thickness direction which corresponds to the laminating direction of the laminated body. Moreover, in the composite material for power generation according to the present invention, the content rate of the ceramic material is 50% or less in any regions along the predetermined direction. In this case, the composite material for power generation can manufactured by setting a content rate of the ceramic material of each of the piezoelectric thin films 50% or less in the method of manufacturing a composite material for power generation according to the present invention. A content rate of the ceramic material of 50% or less can provide crack-resistance and high durability upon repeated loads, vibrations, impacts, and the like.

For the composite material for power generation according to the present invention, the content rate of the ceramic material preferably changes almost continuously. For example, the change in the content rate of the ceramic material may be somewhat steep as long as it changes continuously. In the composite material for power generation according to the present invention, the interface between the polymer and the ceramic material may be subjected to physical or chemical treatment. The composite material for power generation according to the present invention may also include alloy powder having a positive magnetostrictive effect, such as iron cobalt (FeCo) and iron cobalt vanadium (FeCoV) and ceramic powder having a negative magnetostrictive effect, such as a cobalt ferrite (CoFeO) in addition to the polymer and the ceramic material having piezoelectricity. Moreover, the composite material for power generation according to the present invention may be attached to an electrode made of, for example, carbon fiber reinforced plastic and the like in order to obtain toughness.

The present invention can provide a composite material for power generation having relatively superior piezoelectric properties, and a method of manufacturing the composite material for power generation.

### BRIEF DESCRIPTION OF THE DRAWINGS

FIG. 1 is a perspective view illustrating a flow chart for the method of manufacturing a composite material for power generation according to an embodiment of the present invention in Example 1.

FIG. 2 shows a perspective view (tipper panel) and a side view (lower panel) of the composite material for power generation according to an embodiment of the present invention in Example 1 illustrating (a) a sample having a volume fraction of BTO of 30 vol. % as Comparative Example; (b) a sample having a gradually increasing volume fraction of BTO (FGM 1); (C) a sample having a volume fraction of BTO gradually decreasing from both surfaces to the center surface (FGM 2); (d) a sample having a volume fraction of BTO gradually increasing from both surfaces to the center surface (FGM 3).

FIG. 3 shows scanning electron microscope (SEM) images of cross sections of (a) the sample illustrated in FIG. 2(a) as Comparative Example; (b) FGM1 illustrated in FIG. 2(b); (c) FGM 2 illustrated in FIG. 2(c); (d) FGM3 illustrated in FIG. 2(d).

FIG. 4 shows graphs of DSC curves from differential scanning calorimetry of samples each having a constant volume fraction of BTO. The samples each represent Comparative Example of Example 1 for the composite material for power generation according to an embodiment of the present invention.

FIG. 5 shows graphs depicting the piezoelectric constant d₃₃ of each sample from Example 1 for the composite material for power generation according to an embodiment of the present invention.

FIG. 6 shows an overall configuration diagram of a test system for impact power generation tests of Example 1 for the composite material for power generation according to an embodiment of the present invention.

FIG. 7 shows graphs depicting the output voltages from the impact power generation tests of a sample having a volume fraction of BTO of 30 vol. %, FGM1, FGM 2, and FGM 3. The sample having a volume fraction of BTO of 30 vol. % represents Comparative Example of Example 1 for the composite material for power generation according to an embodiment of the present invention.

FIG. 8 shows a perspective view of an overall configuration of a test system for vibration power generation tests of Example 1 for the composite material for power generation according to an embodiment of the present invention.

FIG. 9 shows graphs depicting the output voltages from the vibration power generation tests of a sample having a volume fraction of BTO of 30 vol. %, FGM1, FGM 2, and FGM 3. The sample having a volume fraction of BTO of 30 vol. % represents Comparative Example of Example 1 for the composite material for power generation according to an embodiment of the present invention.

FIG. 10 shows a front view illustrating a finite element analysis model of the composite material for power generation according to an embodiment of the present invention, and (b) a perspective view and boundary conditions of the finite element analysis model.

FIG. 11 shows (a) 6 distribution patterns of the volume fractions of BTO and the potential difference in each of the patterns; (b) 6 distribution patterns of the volume fractions of BTO and the potential difference in each of the patterns. These represent analysis results from the finite element analysis model shown in FIG. 10.

FIG. 12 is a perspective view illustrating a flow chart for the method of manufacturing a composite material for power generation according to an embodiment of the invention in Example 3.

FIG. 13 shows scanning electron microscope (SEM) images of cross sections of (a) a sample AFGC 1, (b) a sample AFGC 2 and (c) a sample AFGC 3; (d) an enlarged SEM image of the central area of (b); and (e) an enlarged SEM image of an area near the center of (b). These samples are from Example 3 for the method of manufacturing a composite material for power generation according to an embodiment of the invention.

FIG. 14 shows graphs depicting the output voltages of the sample AFGC 1 and the sample FGM1 (designated as FCC 1 in the figure) at each frequency (vibration frequency) in the vibration power generation tests. These samples are from Example 3 for the method of manufacturing a composite material for power generation according to an embodiment of the invention.

FIG. 15 shows graphs depicting the output voltages (real-time output voltage) from endurance tests of the sample AFGC 1 from Example 3 for the method of manufacturing a composite material for power generation according to an embodiment of the invention. The elapsed time (Time) is 0 to 4005 sec. in (a) and 4000 to 8005 sec. in (b).

### DETAILED DESCRIPTION OF THE INVENTION

Hereinafter, embodiments of the present invention will be described with reference to Examples and the like.

The composite material for power generation according to an embodiment of the present invention has a plate-like shape having a predetermined thickness. The composite material for power generation according to an embodiment of the present invention comprises a ceramic material having piezoelectricity and a polymer having piezoelectricity, and is configured so that the content rate of the ceramic material changes continuously and gradually along the thickness direction.

The ceramic material may comprise, for example, one having a perovskite structure, such as barium titanate (BaTiO₃; BTO), potassium sodium niobate [(K, Na) NbO₃; KNN], bismuth sodium titanate [(Bi_{1/2}Na_{1/2}) Ti₃; BNT], and bismuth ferrite (BiFeO₃; BF); and the polymer may comprise, for example, polyvinylidene fluoride (PVDF), P(VDF-TrFE) which is a copolymer of polyvinylidene fluoride and trifluoroethylene, or the like.

The composite material for power generation according to an embodiment of the present invention may be configured so that the content rate of the ceramic material gradually increases or decreases, for example, along the thickness direction, or the content rate of the ceramic material is distributed in a plane symmetrical manner with respect to the center plane in the thickness direction.

The composite material for power generation according to an embodiment of the present invention can be manufactured by the method of manufacturing a composite material for power generation according to an embodiment of the present invention. That is, in the method of manufacturing a composite material for power generation according to an embodiment of the present invention, multiple types of piezoelectric thin films comprising a ceramic material having piezoelectricity and a polymer having piezoelectricity; and having different content rates of the ceramic material are first prepared. The piezoelectric thins films may be prepared by any method as long as a piezoelectric thin film having a thin thickness and a uniform concentration can be prepared. For example, each of the piezoelectric thin films may be prepared by a spin coating method using a liquid mixture where the ceramic material and the polymer are added and stirred in a solvent.

After the piezoelectric thin films are prepared, lamination may be performed so that the content rate of the ceramic material gradually changes along their thickness direction, and heat treatment may be then performed. At this time, hot press, for example, may be used to heat each of the laminated piezoelectric thin films under compression in their thickness direction, or each of the laminated piezoelectric thin films may be heated under no compression. Heating at a temperature lower than the recrystallization temperature of each of the piezoelectric thin films can prevent deteriorated piezoelectric properties due to recrystallization. The heat treatment can be performed so that the content rate of the ceramic material changes continuously and gradually, but does not change suddenly at the boundaries of the piezoelectric thin films. In this way, the composite material for power generation according to an embodiment of the present invention can be manufactured.

The composite material for power generation according to an embodiment of the present invention comprises not only a ceramic material but also a flexible polymer, and is thus more durable than a piezoelectric material consisting only of a ceramic material which is susceptible to repeated loads. In addition, it does not require to be attached to an elastic substrate and the like, and is thus highly resistant against vibrations and impacts, showing excellent durability. Moreover, cracking may tend to occur at an interface and the like where the content rate of a ceramic material changes suddenly. However, the composite material for power generation according to an embodiment of the present invention is configured so that the content rate of a ceramic material changes continuously and gradually. The absence of an interface where the content rate of a ceramic material changes suddenly can prevent cracking and can increase durability.

The composite material for power generation according to an embodiment of the present invention has superior piezoelectric properties as compared to a composite material comprising a ceramic material and a non-piezoelectric material because not only the ceramic material but also the polymer has piezoelectricity in the composite material for power generation according to an embodiment of the present invention. The composite material for power generation according to an embodiment of the present invention comprises a ceramic material and a polymer which are different in piezoelectric constants, and is configured so that the content rate of the ceramic material changes gradually. Therefore, various properties can be obtained depending on the magnitude of a value and the changing degree of the content rate thereof.

It is note that in the method of manufacturing a composite material for power generation according to an embodiment of the present invention, multiple types of piezoelectric thin films may be laminated by sequentially preparing a piezoelectric thin film on top of a manufactured piezoelectric thin film instead of first preparing multiple types of piezoelectric thin films and then laminating each of the piezoelectric thin films. In this case, the step of laminating each of the pre-prepared piezoelectric thin films may be omitted, enabling more efficient manufacture in a relatively short time. Each of the piezoelectric thin films may be prepared by a spin coating method even in this case.

### Example 1

Composite materials for power generation ware manufactured by the method of manufacturing a composite material for power generation according to an embodiment of the present invention, and piezoelectric constants were measured, and power generation tests were performed.

### Manufacture of Composite Materials for Power Generation

Among the raw materials for manufacturing a composite material for power generation, BaTiO₃ (BTO, size of 1.04 μm; available from Nippon Chemical Industrial Co., Ltd.) was used as a ceramic material having piezoelectricity, and polyvinylidene fluoride-trifluoethylene P(VDF-TrFE) (“ispp015-1” available from Ideal Star Co., Ltd.) which is a copolymer of polyvinylidene fluoride (PVDF) was used as a polymer having piezoelectricity. BTO is a ferroelectric material that does not contain lead toxic to the body, and has a perovskite structure, and exhibits piezoelectricity when polarized. P(VDF-TrFE) shows piezoelectricity because of the polarization-induced charge bias caused by the difference in electronegativity between hydrogen and fluorine.

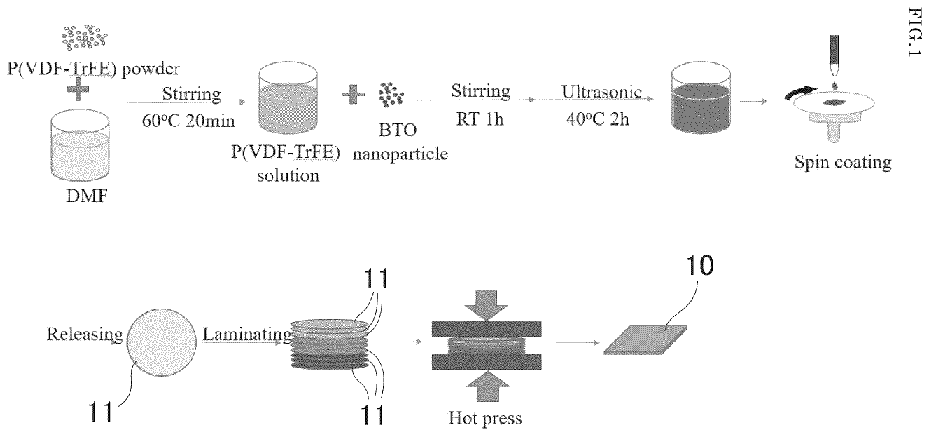

As shown in FIG. 1, in the manufacture of a composite material for power generation, powdered P(VDF-TrFE) was first added to a solvent dimethylformamide (DMF, Fujifilm Corporation) at a weight ratio of P(VDF-TrFE):DMF=10:90, and stirred at 60° C. for 20 minutes with a stirrer (“C-MAG HS4” from IKA-Werke GmbH & Co.). Nanoparticles of BTO were then added to the solution, which was stirred at room temperature for 1 hour with a stirrer, and further ultrasonically irradiated and stirred at 40° C. for 2 hours. The mixed solution after stirring was spread thinly on a silicon wafer with a diameter of 10 mm with a spin coater (MS-B150 available from Mikasa Co., Ltd.), and heated on a hot plate at 90° C. to evaporate the solvent to prepare a piezoelectric thin film 11 comprising BaTiO3/P(VDF-TrFE). In this spin coating method, the spin coater was rotated at a speed of 1000 rpm/sec for 5 seconds, and then slowed down at a rate of −200 rpm/sec.

Six types of piezoelectric thin films 11 were prepared with volume fractions of BTO of 0 vol.%, 10 vol. %, 20 vol. %, 30 vol. %, 40 vol. %, and 50 vol. % relative to P(VDF-TrFE), respectively. The average thickness of each of the piezoelectric thin films 11 was 0.010 mm, 0.012 mm, 0.014 mm, 0.016 mm, 0.018 mm, and 0.020 mm, respectively.

Each of the multiple types of piezoelectric thin films prepared was laminated along the thickness direction, and heated at 130° C. for 30 seconds under compression at 7.5 MPa in the thickness direction by hot press. In this way, the samples 10 of multiple types of composite materials for power generation ware prepared. After hot pressing, each of the samples 10 was cut into a rectangular shape of a desired size. It is noted that the thickness was 0.15 mm.

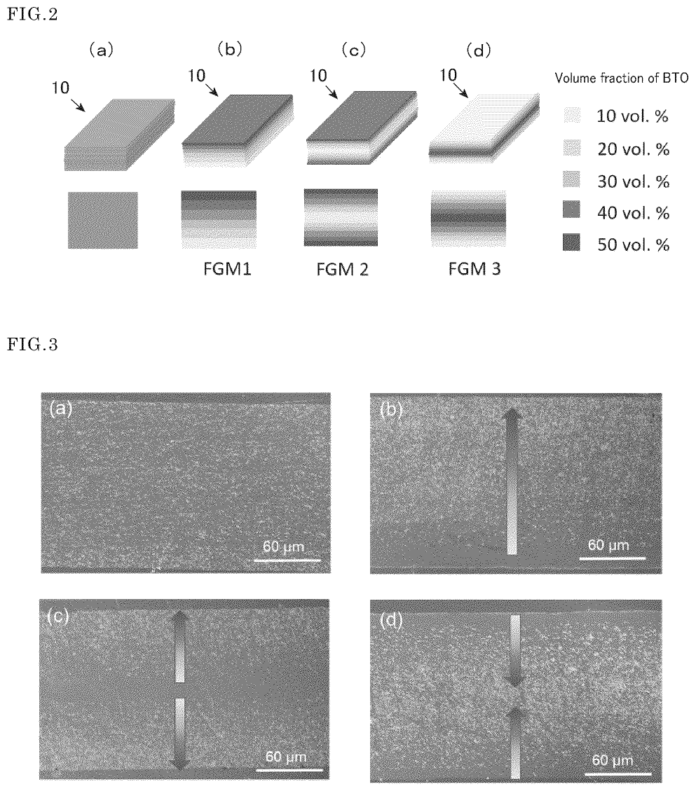

As shown in FIG. 2(a), the samples 10 were first prepared as those with constant volume fractions of BTO (Comparative Example) in which only the piezoelectric thin films 11 with the same volume fraction of BTO were laminated; i.e., 6 types of piezoelectric thin films with a volume fraction of 0 vol. %, 10 vol. %, 20 vol. %, 30 vol. %, 40 vol. %, or 50 vol. % were prepared. In these samples 10, the thicknesses of the piezoelectric thin films 11 varies depending on the volume fractions of BTO. Therefore, 18, 14, 13, 12, 9, and 8 piezoelectric thin films 11 were laminated respectively to obtain a thickness of 0.15 mm after hot press. It is noted that a sample 10 with a volume fraction of BTO of 30 vol. % is shown in FIG. 2(a).

In addition, as shown in FIGS. 2(b) to (d), the following 3 types of samples were prepared as the samples 10 with gradually changing volume fractions of BTO: one in which the piezoelectric thin films 11 were laminated so that the volume fraction of BTO gradually increases from 0 vol. % to 50 vol. % from one surface of the laminated body to the other surface (hereafter referred to as FGM 1); one in which the piezoelectric thin films 11 were laminated so that the volume fraction of BTO gradually decreases from 50 vol. % to 0 vol. % from the surfaces on both sides to the center plane in the thickness direction of the laminated body to achieve plane symmetry with respect to the center plane (hereafter referred to as FGM 2); one in which the piezoelectric thin films 11 were laminated so that the volume fraction of BTO gradually increases from 0 vol. % to 50 vol. % from the surfaces of both sides to the center plane in the thickness direction of the laminated body to achieve plane symmetry with respect to the center plane (hereafter referred to as FGM 3). These 3 types of samples 10 have an average content rate of BTO of 30 vol. %.

Each product of the samples 10 shown in FIG. 2(a) to (d) was covered with epoxy resin, and cross-sectional observation was performed using a scanning electron microscope (SEM; “SU-70” available from Hitachi High-Tech Corporation). The results are shown in FIGS. 3(a) to (d), respectively. As shown in FIGS. 3(a) to (d), the boundaries between the laminated piezoelectric thin films 11 were not observed in each of the samples 10, confirming that they were integrated. In particular, in each of the samples 10 as shown in FIGS. 3(b) to (d), a gradual increase in the volume fraction of BTO was observed along the direction of the arrow in the figure.

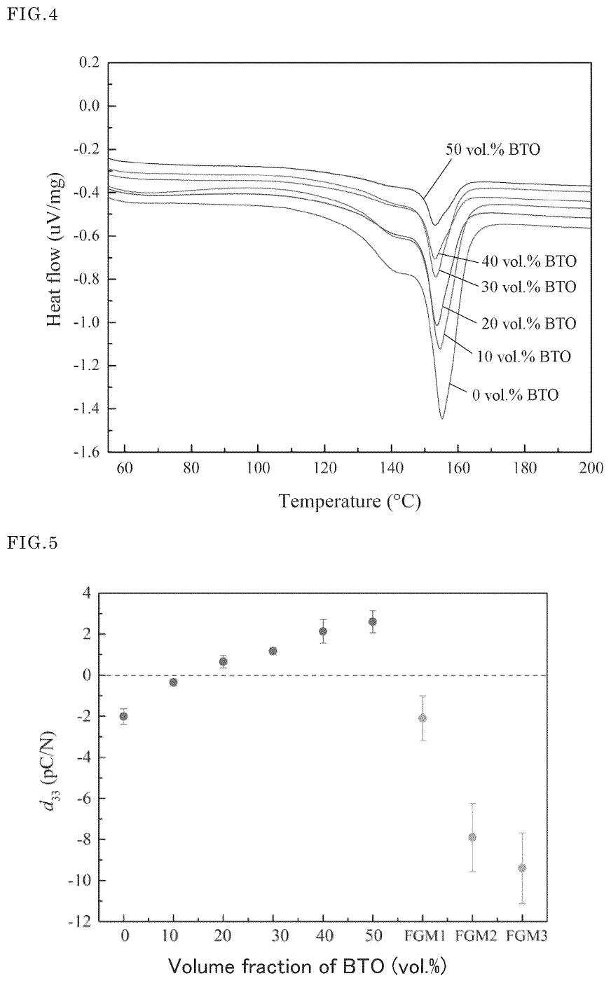

Differential scanning calorimetry (DSC) was performed on each of the samples 10 with a constant volume fraction of BTO using a differential scanning calorimetry analyzer (“DSC 404F3” available from NETZSCH Japan K.K.). The results are shown in FIG. 4. As shown in FIG. 4, it was found that the melting point of each of the samples 10 ranged from 150° C. to 155° C., and the higher the volume fraction of BTO, the lower the melting point. It was also found that the recrystallization temperature was 140° C. From these, it can be said that hot press at 130° C. did not affect the crystal structures of the samples 10.

### Polarization Treatment

In order to confer piezoelectricity on each of the samples 10 prepared, polarization treatment was performed by a corona polarization method using a corona discharge system (“ELC-01N” available from Element Co., Ltd.) In the corona polarization method, a corona discharge is generated between each of the samples 10 and a tungsten needle by applying a high voltage to the tungsten needle placed away from the front surface of each of the samples 10, each of the samples 10 being grounded on the back surface and heated on a hot plate. This can allow an electrical charge to be blown from the tungsten needle onto the surface of each of the samples 10, generating an electric field between the front surface and back surface of each of the samples 10, which in turn results in polarization. It is noted that the voltage applied to the tungsten needle was 7.0 kV and the temperature of the hot plate was 65° C.

### Measurement of Piezoelectric Properties

In a piezoelectric material polarized in the thickness direction, an electric field density D generated upon applying a stress T in the thickness direction under an electric field of zero can be expressed by an equation (1) using the piezoelectric constant d₃₃. The piezoelectric constant d₃₃ can also be obtained by an equation (2) from the equation (1):

$$D = {d}_{33} \times T \qquad ( 1 )$$

$${d}_{33} = D / T = ( Q / A ) / ( F / A ) = Q / F \qquad ( 2 )$$

wherein Q is a surface charge (C), and A is an electrode area (m²), and F is an alternating force (N) applied.

The alternating force F was applied to the back surface of each of the samples 10 prepared, and the charge Q generated was measured with an electrode attached to the front surface of each of the samples 10 to calculate the piezoelectric constant d₃₁ by the equation (2). A piezoelectric d₃₃ meter (“YE2730A” available from Sinocera Piezotronics INC.) was used for the measurement. Positive and negative piezoelectric constants were obtained from the measurements, and thus the piezoelectric constant d₃₃ was defined as the average of the positive and negative piezoelectric constants. The piezoelectric constant d₃₃ calculated for each of the samples 10 is shown in FIG. 5.

As shown in FIG. 5, the followings were observed: P(VDF-TrFE) had a negative piezoelectric constant d₃₃ and BTO had a positive piezoelectric constant d₃₃ for each of the samples 10 with a constant volume fraction of BTO. Therefore, when the volume fraction of BTO was 0 vol. %, the piezoelectric constant d₃₃ was negative. The piezoelectric constant d₃₃, however, increased from negative to positive as the volume fraction of BTO increased. It was also observed that the piezoelectric constant d₃₃ was zero when the volume fraction of BTO was about 10 vol. %.

As shown in FIG. 5, for each of the samples 10 (FGM 1, FGM2, and FGM 3) with a gradually changing volume fraction of BTO, the piezoelectric constant d₃₃ was found to be negative despite the average volume fraction of BTO was 30 vol. %. FGM 1 was found to have a negative piezoelectric constant d₃₃ of almost the same magnitude as that of the sample 10 with a constant volume fraction of BTO of 0 vol. %, and FGM 2 and FGM 3 were found to have a negative piezoelectric constant d₃₃ even larger than that of FGM 1. This may be due to the fact that the samples 10 with gradually changing volume fractions of BTO are affected by the internal stress generated during hot press, i.e., the internal stress may facilitate polarization of the piezoelectric ceramic material and the piezoelectric polymer.

Next, the relative dielectric constant εγ of each of the samples 10 (FGM 1, FGM 2, and FGM 3) with gradually changing volume fractions of BTO was measured with an LCR meter (“ZM2371” available from NF Corporation). Results showed that the relative dielectric constant εγ was about 17 to 18 for each of the samples FGM 1 to 3.

A performance index FoM (figure of merit) of each of the samples FGM 1 to 3 was determined from the above results. FoM can be calculated by d×g=d²×ε, wherein d is a piezoelectric strain constant, and g is a piezoelectric voltage constant, and c is a dielectric constant. FoM represents the energy production efficiency of a piezoelectric material in the 33 mode, and energy harvesting efficiency becomes higher as FoM increases. The FoM of each of the samples was 279 for FGM 1, and 402 for FGM 2, and 551 for FGM 3. This suggests that FGM 3 has the highest energy harvesting efficiency among the samples FGM 1 to 3.

### Impact Power Generation Tests

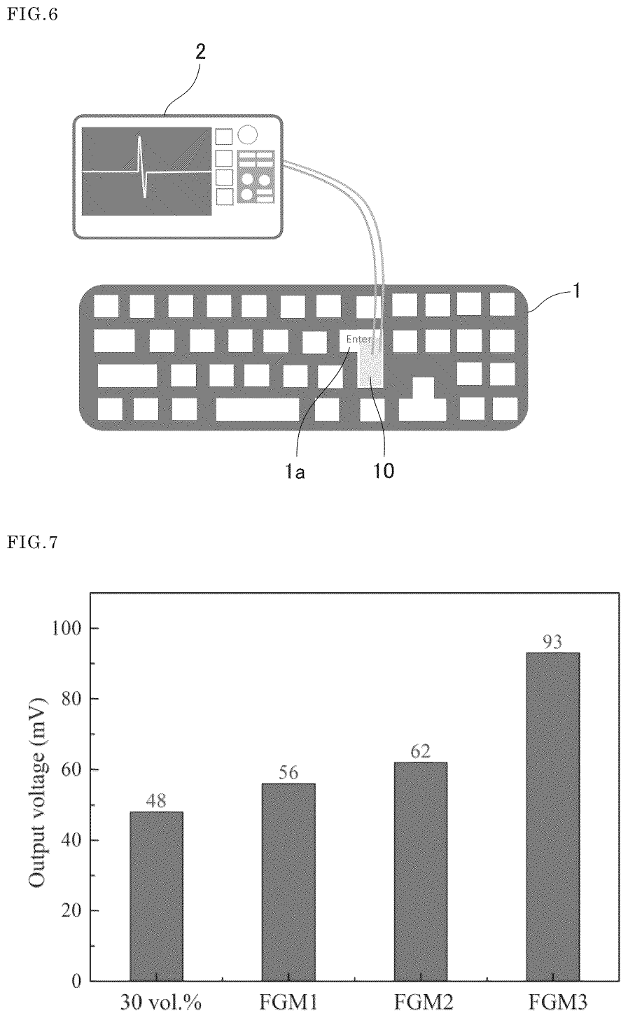

Impact power generation tests were performed on the sample 10 with a constant volume fraction of BTO of 30 vol. % and on each of the samples 10 with a gradually changing volume fraction of BTO. As shown in FIG. 6, the tests examined the amount of power generated by the impact of tapping the surface of each of the samples 10. To do so, each of the samples 10 cut into a 10 mm×20 mm rectangular shape was attached to an enter key 1a of a keyboard 1, and the output voltage when the enter key 1a was pressed was measured with an oscilloscope 2 (“DL850E” available from Yokogawa Electric Corporation). Measurements were performed 200 times on each of the samples, and the average value was considered as a measured value. The measurement results are shown in FIG. 7.

As shown in FIG. 7, each of the samples 10 (FGM 1, FGM 2, and FGM 3) with a gradually changing volume fraction of BTO was found to show a larger output voltage and generate more power than the sample 10 with a constant volume fraction of BTO of 30 vol. %. Among each of the samples 10 with a gradually changing volume fraction of BTO, the output voltage from FGM 3 was found to be particularly large and generate power about 2 times larger than the sample 10 with a constant volume fraction of BTO of 30 vol. %.

### Vibration Power Generation Tests

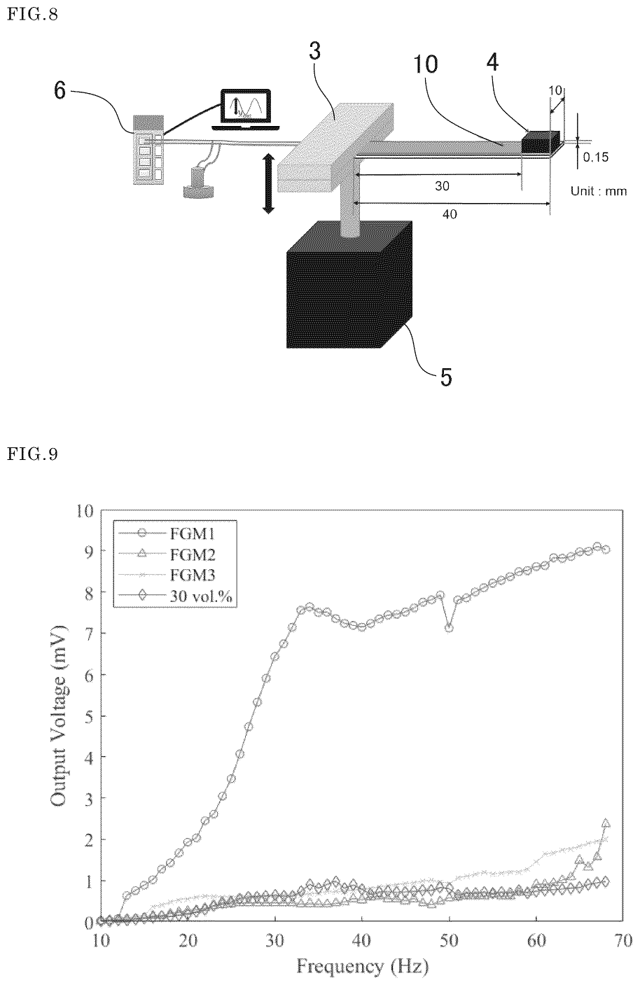

Vibration power generation tests were performed on the sample 10 with a constant volume fraction of BTO of 30 vol. % and on each of the samples 10 with a gradually changing volume fraction of BTO. As shown in FIG. 8, in the tests, one end of each of the samples 10 cut into a 40 mm×10 mm rectangular plate was attached to a vibration generator 3 (“ET-132” available from Labworks Inc.), and a weight 4 of 1.5 g was attached to the other end. A function generator 5 (“FG-281” available from Kenwood Corporation) was used to vibrate each of the samples 10 at a desired frequency, and the output voltage was measured with a data logger 6 (“Keyence NR-500” available from Keyence Corporation). In the tests, the amplitude was set to 0.9 mm, and the frequency varied from 0 to 68 Hz to measure the output voltage at each frequency. The measurement results are shown in FIG. 9.

As shown in FIG. 9, each of the samples 10 was found to show an increased output voltage as the frequency increased. For example, the output voltage at a frequency of 68 Hz was 0.973 mV for the sample 10 with a constant volume fraction of BTO of 30 vol. %, and 9.024 mV for FGM 1, and 2.374 mV for FGM 2, and 1.987 mV for FGM 3. The output voltage of FGM 1 of the samples 10 with a gradually changing volume fraction of BTO was found to be very large, and generate power 5 to 10 times larger than the rest of the samples 10 at a frequency of about 30 Hz or above. This may be due to the fact that the volume fraction of BTO in FGM 1 is asymmetric with respect to the center plane of the thickness. As a result, a larger output voltage was thought to be obtained because a charge generated on one surface (e.g., a surface that becomes outside when bent) upon vibration did not offset a charge generated on the other surface (e.g., a surface that becomes inside when bent). In contrast, the volume fraction of BTO in the rest of the samples 10 is symmetric with respect to the center plane of the thickness. As a result, a smaller output voltage was thought to be obtained because a charge generated on one surface upon vibration did offset a charge generated on the other surface.

### Example 2

Numerical calculations for compressive stress induced voltage were performed on the composite materials for power generation according to an embodiment of the present invention using a simple finite element analysis model.

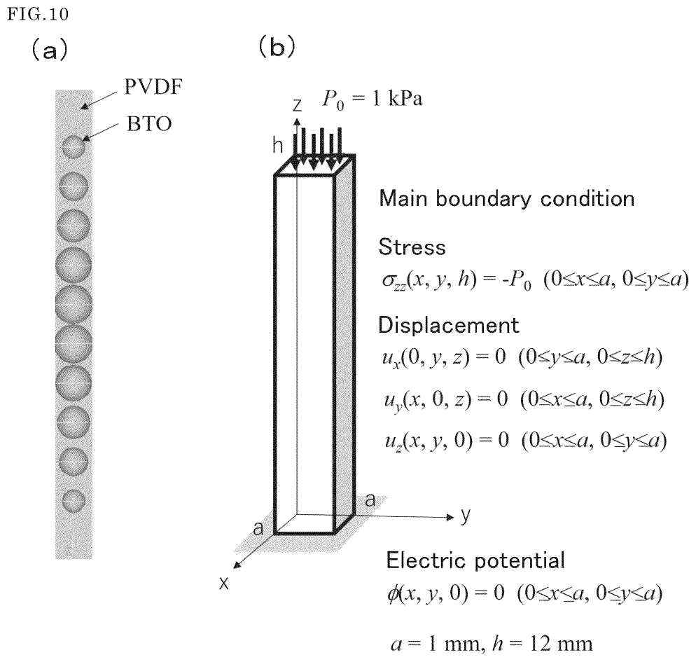

As shown in FIG. 10(a), the finite element analysis model for the composite materials for power generation was based on an assumption that they have an elongated rod shape, and comprise BTO and P(VDF-TrFE), and has a pattern in which the volume fraction of BTO increases gradually from both ends to the center (the pattern of FGM 3 from Example 1). In the finite element analysis model, BTO was assumed to be spherical, and the radius of BTO at each location was adjusted to obtain a desired volume fraction of BTO. Tables 1 to 3 show the material properties of PVDF used in the finite element analysis, the material properties of BTO, and the radius at each volume fraction of BTO, respectively.

TABLE 1
Material Properties of PVDF

Young's modulus E₁₁ = E₂₂ = E₃₃ = 27.7 × 10⁹ N/m²
Poisson ratio ν₁₂ = ν₂₃ = ν₃₁ = 0.2
Piezoelectric coefficient d₃₁ = 0.35 × 10⁻¹² C/N, d₃₂ = 0.6 × 10⁻¹²
C/N, d₃₃ = −1.9 × 10⁻¹² C/N, d₂₄ = −2.5 × 10⁻¹² C/N, d₁₅ = −1.55 ×
10⁻¹² C/N
Dielectric constant ε₁₁ = ε₃₃ = 0.68 × 10⁻¹⁰ C/Vm

TABLE 2
Material Properties of BTO

Elastic compliance coefficient (reciprocal of Young's modulus)
s₁₁ = 8.85 × 10⁻¹² m²/N, s₁₂ = −2.7 × 10⁻¹² m²/N, s₁₃ = −2.9 × 10⁻¹²
m²/N, s₃₃ = 8.95 × 10⁻¹² m²/N, s₄₄ = 22.8 × 10⁻¹² m²/N
Piezoelectric coefficient d₃₁ = −60 × 10⁻¹² C/N, d₃₃ = 140 × 10⁻¹²
C/N, d₁₅ = 260 × 10⁻¹² C/N
Dielectric constant ε₁₁ = 128 × 10⁻¹⁰ C/Vm, ε₃₃ = 150 × 10⁻¹⁰ C/Vm

TABLE 3

| BTO volume fraction (%) | BTO radius (mm) |
|---|---|
| 0 | 0 |
| 10 | 0.288 |
| 20 | 0.363 |
| 30 | 0.415 |
| 40 | 0.457 |
| 50 | 0.492 |

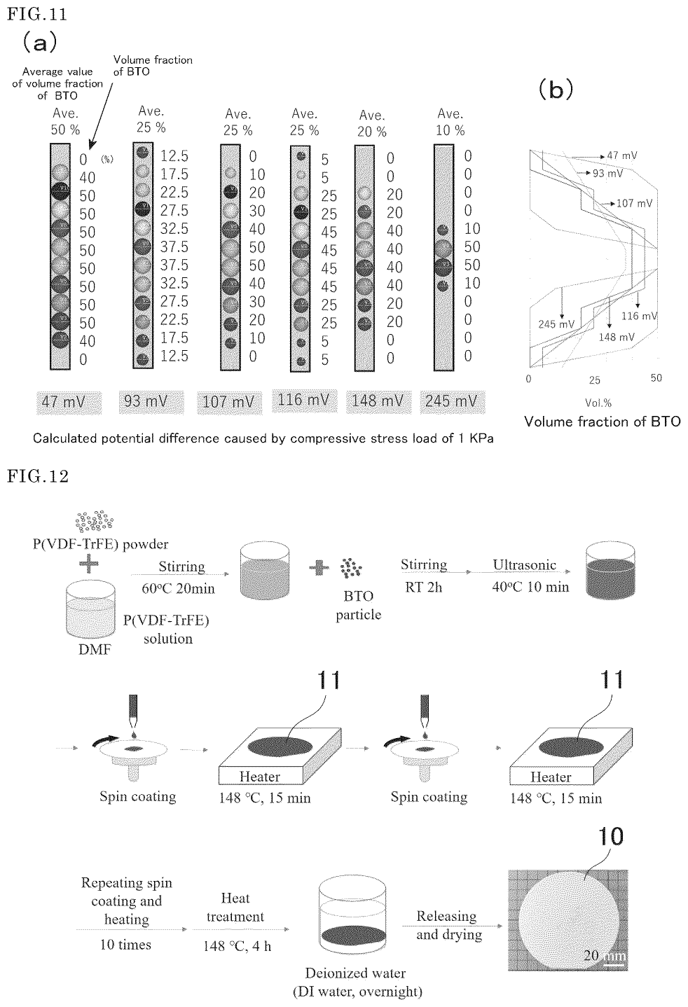

As shown in FIG. 10(b), the shape of the model in the finite element analysis was a square cylinder with a base of 1 mm×1 mm and a height of 12 mm, and the bottom surface of the model (z=0) was fixed. Symmetry conditions were used on the sides of x=0 and y=0, and the electric potential at z=0 was set to 0. In the finite element analysis, the distribution of electric potential was also determined when a compressive stress P₀=1 kPa was applied to the top surface (z=h) of each model as shown in FIG. 10(b) for the models of the 6 patterns of the distributions of volume fractions of BTO as shown in FIGS. 11(a) and (b). From the distributions of the electric potentials, the potential differences caused by a compressive stress load of 1 kPa were also determined. The distribution of the volume fraction of BTO in each model is shown in FIG. 11(a), and the potential differences determined for each model are shown in FIGS. 11(a) and (b).

From the analysis results as shown in FIGS. 11(a) and (b), the output voltage was found to vary depending on how the volume fraction of BTO changes even for a pattern in which the volume fraction of BTO increases gradually from both ends to the center (the pattern of FGM 3 from Example 1). For example, it is expected that increasing the volume fraction of BTO at the center rather than at the ends would lead to greater power generation. It is also expected that even if the overall volume fraction of BTO is small, a sharp increase in the volume fraction of BTO toward the center would lead to larger power generation.

### Example 3

Composite materials for power generation were manufactured by the method of manufacturing a composite material for power generation according to an embodiment of the present invention, and piezoelectric constants were measured, and power generation tests were performed as in Example 1.

### Manufacture of Composite Materials for Power Generation

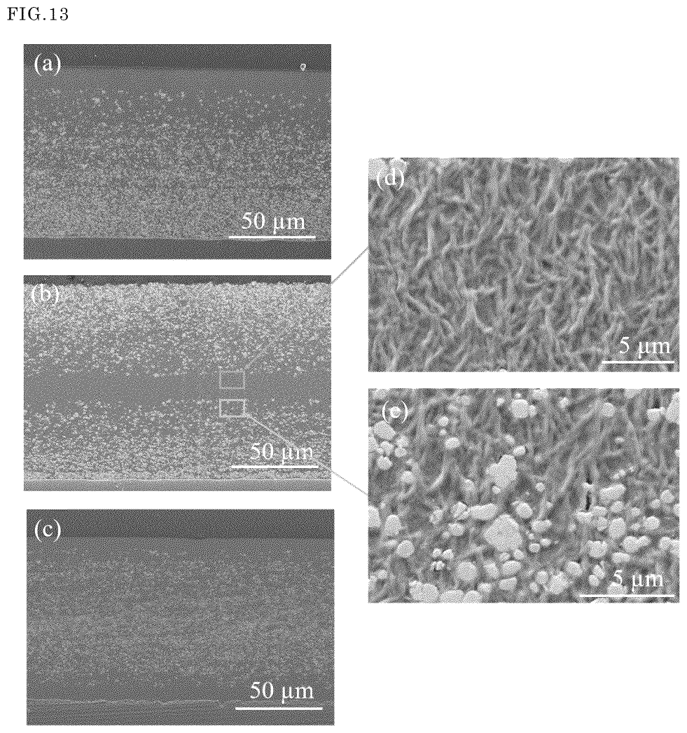

Using the same materials and equipment as in Example 1, 3 samples AFGC 1 to 3 having the same structure as FGM 1 to 3 in FIG. 2 were prepared by a different process than in Example 1. As shown in FIG. 12, powdered P(VDF-TrFE) was first added to a solvent DMF at a weight ratio of P(VDF-TrFE):DMF=10:90, and stirred with a stirrer at 60° C. for 20 minutes. Nanoparticles of BTO were then added to the solution, which was stirred with a stirrer at room temperature for 2 hours, and further ultrasonically irradiated and stirred at 40° C. for 10 minutes. The mixed solution after stirring was spread thinly on a silicon wafer with a diameter of 4 inches and a thickness of 300 μm by a spin coating method, and heated on a hot plate at 148° C. for 15 minutes to evaporate the DMF solvent to prepare the bottommost layer of a piezoelectric thin film 11. Similarly, the piezoelectric thin films 11 were sequentially prepared on top of a prepared piezoelectric thin film 11 such that a total of 12 piezoelectric thin films 11 were laminated. It is noted that in the spin coating method, it was rotated a rotational speed of 500 rpm/sec for 5 seconds with acceleration of 100 rpm/sec, and then a rotational speed of 1000 rprn/sec for 5 seconds, and then deaccelerated at −200 rpm/sec for each manufacture of the piezoelectric thin films 11.

After laminating all the piezoelectric thin films 11, heat treatment was performed at 148° C. for 4 hours. Each sample after heat treatment was immersed into deionized water (DI water) along with a wafer overnight, and then each sample was removed from the wafer and dried. In this way, each of the samples 10 of AFGC 1 to 3 was manufactured. The thickness of each of the manufactured samples AFGC 1 to 3 is shown in Table 4.

TABLE 4

| | | | Piezoelectric | Relative |
|---|---|---|---|---|
| | Thickness at | Thickness at | constant | dielectric |
| | end (μm) | center (μm) | (pCN⁻¹) | constant (ε_{γ}) |
| AFGC 1 | 173 | 115 | −10.6 | 14 |
| AFGC 2 | 211 | 143 | −8.02 | 12 |
| AFGC 3 | 187 | 116 | −8.13 | 11 |

It is noted that the step of laminating each of the manufactured piezoelectric thin films 11 one by one can be omitted in this method of manufacture, and composite materials for power generation can be efficiently manufactured in a relatively short time. Moreover, immersing each sample after treatment into deionized water along with the wafer overnight can allow each of the samples 10 to be detached from the wafer without destruction due to shrinkage of the piezoelectric film 11 in the bottommost layer.

As shown in Table 4, each of the samples AFGC 1 to 3 has a central portion thicker than the ends due to the accumulation of a solution by the spin coating method. For this reason, a test piece was cut from the central portion of each of the samples AFGC 1 to 3 when using each of the samples AFGC 1 to 3.

The cross sections of the manufactured samples AFGC 1 to 3 were observed by scanning electron microscopy. The results are shown in FIGS. 13(a) to (e), respectively. As shown in FIGS. 13(a) to (c), no boundaries between the laminated piezoelectric thin films were observed in each of the samples A-FGC 1 to 3, confirming that they were integrated and the volume fraction of BTO was found to change gradually. As shown in FIGS. 13(d) to (e), it was observed that BTO was embedded in dendritically crystallized P(VDF-TrFE) crystals, and P(VDF-TrFE) was bonded with BTO.

### Polarization Treatment

Each of the samples AFGC 1 to 3 manufactured as in Example 1 was polarized by a corona polarization method to develop piezoelectricity. In the polarization treatment, each sample was polarized in the thickness direction at 65° C. for 30 minutes at 52 kV/mm².

### Measurement of Piezoelectric Properties

The piezoelectric constant d₃₃ and relative dielectric constant &, of each of the manufactured samples AFGC 1 to 3 were measured as in Example 1. The measurement results are shown in Table 4. As shown in Table 4, AFGC 1 was found to show the largest negative piezoelectric constant d₃₃, and AFGC 2 and AFGC 3 were also found to have almost the same negative value. Moreover, each of the samples AFGC 1 to 3 was found to have a relative dielectric constant ε_{γ} of about 11 to 14. When comparing the value of piezoelectric constant d₃₃ of each of the samples AFGC 1 to 3 with the value of piezoelectric constant d₃₃ of each of the samples from Example 1 as shown in FIG. 5, AFGC 2 and AFGC 3 were found to have almost the same value as FGM 2 and FGM 3 having the same structure, while AFGC 1 was found to have a value about 1.6 times higher than FGM 1 having the same structure. This may be due to differences in the manufacturing process for each sample, i.e., the presence or absence of a hot press step and the uniformity of heat transfer during hot press in manufacture of the sample FGM 1 in Example 1.

From these results, the performance index FoM for each of the samples AFGC 1 to 3 was determined as in Example 1. The FoM of each sample was 884 for AFGC 1, and 593 for AFGC 2, and 679 for AFGC 3. Comparing these FoM values with the FoM values of each of the samples FGM 1 to 3 from Example 1, each of the samples AFGC 1 to 3 had a larger value than each of the samples FGM 1 to 3 having the corresponding structure. This suggests that each of the samples AFGC 1 to 3 has a higher energy harvesting efficiency than each of the samples FGM 1 to 3. Of each of the samples AFGC 1 to 3, AFGC 1 has the largest FoM, suggesting that AFGC 1 has the highest energy harvesting efficiency.

### Vibration Power Generation Tests

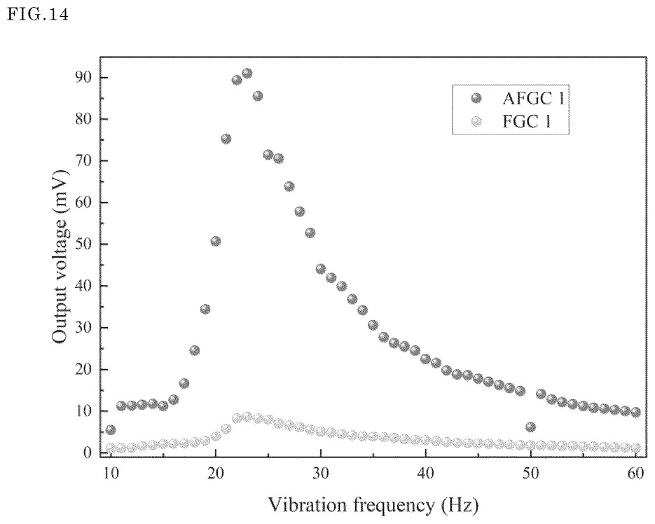

Vibration power generation tests were performed on the sample AFGC 1 as in Example 1. The tests were performed using a similar equipment as shown in FIG. 8, except that the length of the sample AFGC 1 was 30 mm. The tests used sinusoidal vibrations with an amplitude of 0.9 mm and a frequency of 10 to 50 Hz, and the output voltage was measured at each frequency. It is noted that the sample FGM 1 prepared in Example 1 was also measured in a similar way. The measurement results are shown in FIG. 14.

As shown in FIG. 14, a peak in the output voltage was observed for each of the samples AFGC 1 and FGM 1 (denoted as FGC 1 in the figure), and the resonant frequency at the peak was found to be about 23 Hz for both samples. The output voltage at the resonant frequency was found to be about 91 mV for the sample AFGC 1, which was about 10 times higher than the output voltage of the sample FGM 1 (about 9 mV). This is thought to be due to the difference in the methods of manufacturing each of the samples AFGC 1 and FGM 1. It is thought that in the sample AFGC 1, each of the piezoelectric thin films 11 was more tightly bonded than in the sample FGM 1 to facilitate polarization and improved piezoelectricity.

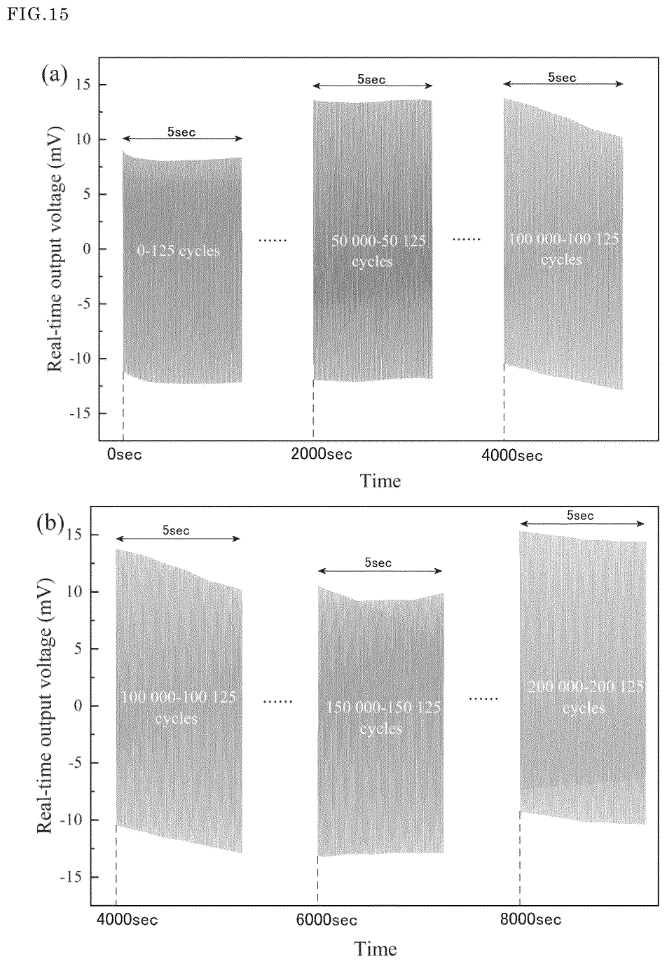

To investigate the durability of the sample AFGC 1, a system for vibration power generation tests was used to vibrate the sample at an amplitude of 0.9 mm and a frequency of 25 Hz for measuring a real-time output voltage for 5 seconds (125 cycles) every 50000 cycles (2000 seconds) up to 200000 cycles. The measurement results are shown in FIGS. 15(a) and (b). As shown in FIG. 15, no decrease in the output voltage was observed even after 200000 cycles. From this, it can be said that the sample AFGC 1 has excellent durability.

### REFERENCE SIGNS LIST

1: Keyboard
1a: Enter key
2: Oscilloscope
3: Vibration Generator
4: Weight
5: Function Generator
6: Data Logger
10: Sample (of Composite Material for Power Generation)
11: Piezoelectric Thin Film

1. A composite material for power generation comprising a ceramic material having piezoelectricity and a polymer having piezoelectricity, and configured so that the content rate of the ceramic material changes gradually and continuously along a predetermined direction and a piezoelectric constant is negative.

2. The composite material for power generation according to claim 1, configured so that the content rate of the ceramic material increases or decreases gradually and continuously along the predetermined direction.

3. The composite material for power generation according to claim 1, configured so that the content rate of the ceramic material along the predetermined direction is distributed in a plane symmetrical manner with respect to a central plane in the predetermined direction.

4. The composite material for power generation according to claim 1, configured so as to have a region where the content rate of the ceramic material increases and a region where the content rate of the ceramic material decreases along the predetermined direction.

5. The composite material for power generation according to claim 1, wherein the ceramic material has a perovskite structure.

6. The composite material for power generation according to claim 1, wherein
the ceramic material comprises at least one or more of barium titanate (BaTiO₃; BTO), potassium sodium niobate [(K,Na)NbO₃; KNN], bismuth sodium titanate [(Bi_{1/2}Na_{1/2})Ti₃; BNT], and bismuth ferrite (BiFeO₃; BF), and
the polymer comprises at least one of either polyvinylidene fluoride (PVDF) or P(VDF-TrFE) which is a copolymer of polyvinylidene fluoride and trifluoroethylene.

7. The composite material for power generation according to claim 1, having a plate-like shape and a thickness direction corresponding to the predetermined direction.

8. A method of manufacturing a composite material for power generation, the method comprising the steps of: laminating multiple types of piezoelectric thin films comprising a ceramic material having piezoelectricity and a polymer having piezoelectricity, the multiple types of piezoelectric thin films having different content rates of the ceramic material; so that the content rate of the ceramic material gradually changes along their thickness direction, and then performing heat treatment.

9. The method of manufacturing a composite material for power generation according to claim 8, wherein the heat treatment is performed by heating each of the piezoelectric thin films laminated, at a temperature lower than the recrystallization temperature of each of the piezoelectric thin films under compression in their thickness direction.

10. The method of manufacturing a composite material for power generation according to claim 8, wherein each of the piezoelectric thin films are prepared by a spin coating method using a liquid mixture where the ceramic material and the polymer are added and stirred in a solvent.

11. The method of manufacturing a composite material for power generation according to claim 8, wherein each of the piezoelectric thin films is laminated after each of the piezoelectric thin films are prepared.

12. The method of manufacturing a composite material for power generation according to claim 8, wherein each of the piezoelectric thin films is laminated by sequentially preparing a piezoelectric thin film on top of a piezoelectric thin film manufactured.

13. The method of manufacturing a composite material for power generation according to claim 8, wherein the ceramic material has a perovskite structure.

14. The method of manufacturing a composite material for power generation according to claim 8, wherein
the ceramic material comprises at least one or more of barium titanate (BaTiO₃; BTO), potassium sodium niobate [(K,Na)NbO₃; KNN], bismuth sodium titanate [(Bi_{1/2}Na_{1/2})Ti₃; BNT], and bismuth ferrite (BiFeO₃; BF), and
the polymer comprises at least one of either polyvinylidene fluoride (PVDF) or P(VDF-TrFE) which is a copolymer of polyvinylidene fluoride and trifluoroethylene.

15. The method of manufacturing a composite material for power generation according to claim 8, wherein a laminated body prepared by laminating each of the piezoelectric thin films has a plate-like shape and a thickness direction corresponding to a laminating direction of the laminated body.
